(19) United States
(12) Patent Application Publication
(10) Pub. No.: US 2007/0045520 A1
(43) Pub. Date: Mar. 1, 2007

(54) Photoelectric conversion device and imaging device

(75) Inventor: Tetsuro Mitsui, Kanagawa (JP)

Correspondence Address: SUGHRUE-265550, 2100 PENNSYLVANIA AVE. NW, WASHINGTON, DC, 20037-3213, US

(73) Assignee: FUJI PHOTO FILM CO., LTD.

(21) Appl. No.: 11/508,155

(22) Filed: Aug. 23, 2006

(30) Foreign Application Priority Data
Aug. 23, 2005 (JP) P2005-240963

(51) Int. Cl. H01L 31/00; H03F 3/08

(52) U.S. Cl. 250/214 R; 136/252; 250/214.1

(57) ABSTRACT

A photoelectric conversion device comprising: a substrate; a conducting layer; a photoelectric conversion layer; and a transparent conducting layer provided in this order, wherein the transparent conducting layer has a thickness of not more than ⅕ of that of the photoelectric conversion layer.

The present invention relates to a solid imaging device including a transparent electrode in an upper part of a photoelectric conversion layer and provides a solid imaging device which is high in sensitivity and low in noise and which is high in yield.

### BACKGROUND OF THE INVENTION

In a photoelectric conversion device which is made of a photoelectric conversion part having a transparent electrode formed thereon, for the purpose of increasing the absolute amount of incident light into the photoelectric conversion part to enhance the carrier read-out efficiency after the photoelectric conversion, there have hitherto been demanded ones having a higher light transmittance of the transparent electrode. In the case of taking into consideration such high light transmittance and low resistance value, it is generally thought that a transparent conducting oxide (TCO) thin layer is preferable. In general, the formation of a TCO transparent electrode is carried out by a sputtering method. In that case, in comparison with an Al electrode and so on, an increase of the leakage current which is considered to be caused due to an increase of a short circuit part is liable to be generated. Also, there are caused problems such as deterioration of S/N, scattering of the performance, and the generation of a complete DC short circuit so that the device does not drive according to circumstances.

Usually, in the case where a transparent conducting oxide thin layer is subjected to film formation on an organic layer by sputtering or the like, for the purpose of reducing the damage to the organic layer, there is known a method for thinly stacking a metallic layer or a specific organic material layer as a protective layer on the organic layer. In this way, though there may be the case where the increase of the leakage current can be reduced, there was some possibility that the introduction of such a protective layer causes the deterioration of other performances of the device.

JP-A-5-299682 is concerned with a photoelectromotive device. However, this patent document describes only that the thickness of a transparent electrode is preferably from 1 to 1,000 nm but does not describe at all a ratio of the thickness of a transparent conducting thin layer to the thickness of a photoelectric conversion thin layer. Also, JP-A-2003-332551 is concerned with a stacking type solid imaging device and describes an example of an 80 nm-thick Ag electrode as an electrode in the light incidence side as formed on a photoelectric conversion layer on a substrate. However, in that case, the light transmittance of the layer itself is low so that it cannot be said that this electrode is a transparent electrode; the light incidence is achieved by providing an opening; and this patent document does not mention the thickness and ratio of the photoelectric conversion layer and a transparent conducting layer as stacked thereon into which the light can be made incident.

### SUMMARY OF THE INVENTION

An object of the invention is to provide a solid imaging device having an upper transparent electrode which is improved with respect to an increase of dark current, deterioration of yield and scattering of device performance.

The foregoing object of the invention has bee achieved by the following measures.

(1) A photoelectric conversion device comprising a substrate having a conducting thin layer, a photoelectric conversion layer and a transparent conducting thin layer stacked thereon in this order, wherein the transparent conducting thin layer has a thickness of not more than ⅕ of that of the photoelectric conversion layer.

(2) The photoelectric conversion device as set forth in (1), wherein the transparent conducting thin layer has a thickness of not more than 1/10 of that of the photoelectric conversion layer.

(3) A photoelectric conversion device comprising a substrate having a conducting thin layer, a photoelectric conversion layer and a transparent conducting thin layer stacked thereon in this order, wherein the transparent conducting thin layer has a thickness of 5 nm or more and not more than 30 nm.

(4) The photoelectric conversion device as set forth in any one of (1) to (3), wherein the photoelectric conversion layer has a thickness of not more than 350 nm.

(5 The photoelectric conversion device as set forth in any one of (1) to (4), wherein the transparent conducting thin layer is made of a transparent conducting oxide.

(6) The photoelectric conversion device as set forth in any one of (1) to (5), wherein the transparent conducting thin layer has a light transmittance of 75% or more at a light wavelength in the range of from 400 to 700 nm.

(7) The photoelectric conversion device as set forth in any one of (1) to (6), wherein the transparent conducting thin layer has a sheet resistance of 100 Ω/□ or more and not more than 10,000 Ω/□.

(8) The photoelectric conversion device as set forth in any one of (1) to (7), wherein the transparent conducting thin layer is subjected to film formation by a plasma-free method.

(9) The photoelectric conversion device as set forth in any one of (1) to (8), wherein the photoelectric conversion layer includes a pigment based material layer.

(10) The photoelectric conversion device as set forth in (9), wherein the pigment based material layer has a thickness of 75 nm or more.

(11) The photoelectric conversion device as set forth in (9) or (10), wherein the pigment based material layer has a thickness of 100 m or more.

(12) A photoelectric conversion device including an inorganic photoelectric conversion layer within a semiconductor substrate and the photoelectric conversion layer as set forth in any one of (1) to (11) stacked above the inorganic photoelectric conversion layer.

(13) An imaging device including the photoelectric conversion device as set forth in any one of (1) to (12).

According to the invention, it is possible to provide a photoelectric conversion device which is high in sensitivity and low in noise and which is able to increase the yield of the device.

### BRIEF DESCRIPTION OF THE DRAWINGS

FIG. 1 is a schematic cross-sectional view of a photoelectric conversion device of a preferred embodiment of the invention.

### DETAILED DESCRIPTION OF THE INVENTION

The invention is characterized in that in a photoelectric conversion device comprising a substrate having a conducting thin layer, a photoelectric conversion layer and a transparent conducting thin layer stacked thereon in this order, the transparent conducting thin layer has a thickness of not more than ⅕, and preferably not more than 1/10 of that of the photoelectric conversion layer.

The “photoelectric conversion layer” as referred to in the invention means a layer which contains a layer made of a semiconductor such as an n-type semiconductor and a p-type semiconductor and a charge transport layer and which is interposed between a counter electrode (preferably, a transparent conducting thin layer) and a pixel electrode (preferably, a conducting thin layer). The photoelectric conversion layer of the invention preferably has a thickness of not more than 350 nm, more preferably not more than 300 nm, and further preferably not more than 200 nm.

It is thought that one of causes of the increase of the leakage current which is generated when a transparent conducting thin layer such as a transparent conducting oxide (TCO) is stacked on a photoelectric conversion layer resides in the matter that fine cracks which are introduced into the photoelectric conversion layer are covered by a minute layer such as TCO, whereby the continuity with the conducting thin layer in the opposite side increases. For that reason, in the case of an electrode which is inferior in layer quality, such as Al, the leakage current is not bigger than that in case TCO is provided. Taking into account the foregoing phenomena and studies, in the invention, it has been found that by controlling the thickness of the transparent conducting thin layer with respect to the thickness of the photoelectric conversion layer (namely, the crack depth), the increase of the leakage current can be largely suppressed. It is desired that the thickness of the transparent conducting thin layer is not more than ⅕, and preferably not more than 1/10 (preferably 1/100 or more) of the thickness of the photoelectric conversion layer.

Usually, when the conducting thin layer is thinner than a certain range, an abrupt increase of the resistance value is brought. In the photoelectric conversion device of the invention, the sheet resistance may be preferably 100 Ω/□ or more and not more than 10,000 Ω/□, and the degree of freedom with respect to the range of the thickness in which the layer can be thinned is large. Furthermore, when the thickness of the transparent conducting thin layer is thin, the amount of light to be absorbed becomes small, and the light transmittance generally increases. The increase of the light transmittance is very preferable because the light absorption in the photoelectric conversion layer is increased and the light conversion ability is increased. Taking into account the suppression of the leakage current, the increase of the resistance value of the thin layer and the increase of the light transmittance following thinning of the layer, it is desired that the thickness of the transparent conducting thin layer is 5 nm or more and not more than 30 nm, and preferably 5 nm or more and not more than 15 nm.

The light transmittance of the transparent conducting thin layer is preferably 75% or more, more preferably 80% or more, further more preferably 90% or more, and still more preferably 95% or more at a light wavelength in the range of from 400 to 700 nm.

The effect of the invention is remarkably revealed in the case where a minuter layer is applied as the transparent conducting thin layer. It is thought that a transparent conducting oxide (TCO) is preferable as the transparent conducting thin layer because of its high light transmittance and low resistivity. In general, since in a transparent conducting oxide (TCO) layer, a minute layer is formed against a metal thin layer of Al, etc., the effect of the invention is remarkably revealed.

The effect of the invention is especially remarkable against a photoelectric conversion layer including a crystalline layer (namely, grain boundary-containing layer) in which cracks are likely formed. In the case where an organic thin layer is applied as the photoelectric conversion layer, when a pigment based material is contained in the photoelectric conversion layer, the effect of the invention is large. Furthermore, since the non-uniformity of the layer increases, when the thickness due to the pigment based material increases, the effect of the invention becomes larger. In order to bring light absorption or sufficient photoelectric conversion performance, it is better that the thickness of the pigment based material is thick within a certain range. The thickness of the pigment based material is preferably 75 nm or more, and more preferably 100 nm or more (preferably not more than 1,000 nm). The grain boundary is confirmed by an electron microscope or the like.

Examples of the pigment based material include usual pigments, namely organic pigments and inorganic pigments. In the invention, such a material is a substance which is substantially insoluble in water or an organic solvent and which is capable of forming the foregoing crystalline layer. Furthermore, even a substance which is soluble in water or an organic solvent is included so far as it is used in a solid state, thereby forming a crystalline layer. The pigment based material is preferably an organic pigment, and examples of the organic pigment include dyes as described later. That is, pigments among the p-type organic dyes or n-type organic dyes are preferably used.

In the case where an organic layer is supposed as the photoelectric conversion layer, when the transparent conducting thin layer is subjected to film formation by a usual sputtering method or the like, there is some possibility that the performance of the photoelectric conversion layer is deteriorated by the damage by plasma. For that reason, the film formation of the transparent conducting thin layer is preferably carried out by a plasma-free method. Here, the term “plasma-free state” means a state that plasma is not generated during the film formation of a transparent electrode layer, or a distance from the plasma generation source to the substrate is 2 cm or more, preferably 10 cm or more, and more preferably 20 cm or more and that the plasma which reaches the substrate is reduced.

Examples of a device in which plasma is not generated during the film formation of a transparent electrode layer include an electron beam vapor deposition device (EB vapor deposition device) and a pulse laser vapor deposition device. With respect to the EB vapor deposition device or pulse laser vapor deposition device, devices as described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used. In the following, the method for achieving film formation of a transparent electrode film using an EB vapor deposition device is referred to as “EB vapor deposition method”; and the method for achieving film formation of a transparent electrode film using a pulse laser vapor deposition device is referred to as “pulse laser vapor deposition method”.

With respect to the device capable of realizing the state that a distance from the plasma generation source to the substrate is 2 cm or more and that the plasma which reaches the substrate is reduced (hereinafter referred to as “plasma-free film formation device”), for example, a counter target type sputtering device and an arc plasma vapor deposition method can be thought. With respect to these matters, devices as described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used.

The substrate temperature as the time of film formation of the conducting thin layer and the transparent conducting thin layer is preferably not higher than 500° C., more preferably not higher than 300° C., further preferably not higher than 200° C., and still further preferably not higher than 150° C.

Examples of materials for the conducting thin layer and the transparent conducting thin layer which meet the requirements of the invention include conducting metal oxides such as tin oxide, zinc oxide, indium oxide, and indium tin oxide (ITO); metals such as gold, silver, chromium, and nickel; mixtures or stacks of these metals and conducting metal oxides; transparent conducting oxides (TCO) such as copper iodide and copper sulfide; organic conducting materials such as polyaniline, polythiophene, and polypryrrole; silicon compounds; and stacks thereof with ITO. Above all, conducting metal oxides are preferable; In₂O₃ based materials and ZnO based materials are more preferable; ITO and IZO are especially preferable in view of productivity, high conductivity, transparency, and so on.

(Photoelectric Conversion Device)

The photoelectric conversion device of the invention will be hereunder described.

The photoelectric conversion device of the invention is comprised of an electromagnetic wave absorption/photoelectric conversion site (including a conducting thin layer, a photoelectric conversion layer, and a transparent conducting thin layer) and a charge storage of charge as generated by photoelectric conversion/transfer/and read-out site.

In the invention, the electromagnetic wave absorption/photoelectric conversion site has a stack type structure made of at least two layers, which is capable of absorbing each of blue light, green light and red light and undergoing photoelectric conversion. A blue light absorbing layer (B) is able to absorb at least light of 400 nm or more and not more than 500 nm and preferably has an absorptance of a peak wavelength in that wavelength region of 50% or more. A green light absorbing layer (G) is able to absorb at least light of 500 nm or more and not more than 600 nm and preferably has an absorptance of a peak wavelength in that wavelength region of 50% or more. A red light absorbing layer (R) is able to absorb at least light of 600 nm or more and not more than 700 nm and preferably has an absorptance of a peak wavelength in that wavelength region of 50% or more. The order of these layers is not limited. In the case of a three-layer stack type structure, orders of BGR, BRG, GBR, GRB, RBG and RGB from the upper layer (light incident side) are possible. It is preferable that the uppermost layer is G In the case of a two-layer stack type structure, when the upper layer is an R layer, a BG layer is formed as the lower layer in the same planar state; when the upper layer is a B layer, a GR layer is formed as the lower layer in the same planar state; and when the upper layer is a G layer, a BR layer is formed as the lower layer in the same planar state. It is preferable that the upper layer is a G layer and the lower layer is a BR layer in the same planar state. In the case where two light absorbing layers are provided in the same planar state of the lower layer in this way, it is preferable that a filter layer capable of undergoing color separation is provided in, for example, a mosaic state on the upper layer or between the upper layer and the lower layer. Under some circumstances, it is possible to provide a fourth or polynomial layer as a new layer or in the same planar state.

In the invention, the charge storage/transfer/read-out site is provided under the electromagnetic wave absorption/photoelectric conversion site. It is preferable that the electromagnetic wave absorption/photoelectric conversion site which is the lower layer also serves as the charge storage/transfer/read-out site.

In the invention, the electromagnetic wave absorption/photoelectric conversion site is made of an organic layer or an inorganic layer or a mixture of an organic layer and an inorganic layer. The organic layer may form a B/G/R layer or the inorganic layer may form a B/G/R layer. It is preferable that the electromagnetic wave absorption/photoelectric conversion site is made of a mixture of an organic layer and an inorganic layer. In this case, basically, when the organic layer is made of a single layer, the inorganic layer is made of a single layer or two layers; and when the organic layer is made of two layers, the inorganic layer is made of a single layer. When each of the organic layer and the inorganic layer is made of a single layer, the inorganic layer forms an electromagnetic wave absorption/photoelectric conversion site of two or more colors in the same planar state. It is preferable that the upper layer is made of an organic layer which is constructed of a G layer and the lower layer is made of an inorganic layer which is constructed of a B layer and an R layer in this order from the upper side. Under some circumstances, it is possible to provide a fourth or polynomial layer as a new layer or in the same planar state. When the organic layer forms a B/G/R layer, a charge storage/transfer/read-out site is provided thereunder. When an inorganic layer is used as the electromagnetic wave absorption/photoelectric conversion site, this inorganic layer also serves as the charge storage/transfer/read-out site.

(Organic Layer)

The organic layer of the invention will be hereunder described. An electromagnetic wave absorption/photoelectric conversion site made of an organic layer of the invention is made of an organic layer which is interposed between one pair of electrodes. The organic layer is formed by superposing or mixing a site for absorbing electromagnetic waves, a photoelectric conversion site, an electron transport site, a hole transport site, an electron blocking site, a hole blocking site, a crystallization preventing site, an electrode, an interlaminar contact improving site, and so on. It is preferable that the organic layer contains an organic p-type compound or an organic n-type compound. The organic p-type semiconductor (compound) is an organic semiconductor (compound) having donor properties and refers to an organic compound which is mainly represented by a hole transport organic compound and which has properties such that it is liable to provide an electron. In more detail, the organic p-type semiconductor refers to an organic compound having a smaller ionization potential in two organic compounds when they are brought into contact with each other and used. Accordingly, with respect to the organic compound having donor properties, any organic compound can be used so far as it is an electron donating organic compound. Useful examples thereof include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, fused aromatic carbocyclic compounds (for example, naphthalene derivatives, anthracene derivatives, phenanthrene derivatives, tetracene derivatives, pyrene derivatives, perylene derivatives, and fluoranthene derivatives), and metal complexes having, as a ligand, a nitrogen-containing heterocyclic compound. Incidentally, the invention is not limited to these compounds, and as described previously, an organic compound having a smaller ionization potential than that of an organic compound to be used as an n-type compound (having acceptor properties) may be used as the organic semiconductor having donor properties.

The organic n-type semiconductor (compound) is an organic semiconductor (compound) having acceptor properties and refers to an organic compound which is mainly represented by an electron transport organic compound and which has properties such that it is liable to accept an electron. In more detail, the organic n-type semiconductor refers to an organic compound having a larger electron affinity in two organic compounds when they are brought into contact with each other and used. Accordingly, with respect to the organic compound having acceptor properties, any organic compound can be used so far as it is an electron accepting organic compound. Useful examples thereof include fused aromatic carbocyclic compounds (for example, naphthalene derivatives, anthracene derivatives, phenanthroline derivatives, tetracene derivatives, pyrene derivatives, perylene derivatives, and fluoranthene derivatives), 5- to 7-membered heterocyclic compounds containing a nitrogen atom, an oxygen atom or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazepine, and tribenzazepine), polyarylene compounds, fluorene compounds, cyclopentadiene compounds, silyl compounds, and metal complexes having, as a ligand, a nitrogen-containing heterocyclic compound. Incidentally, the invention is not limited to these compounds, and as described previously, an organic compound having a larger electron affinity than that of an organic compound to be used as an organic compound having donor properties may be used as the organic semiconductor having acceptor properties.

Though any organic dye is useful as the p-type organic dye or n-type organic dye, preferred examples thereof include cyanine dyes, styryl dyes, hemicyanine dyes, merocyanine dyes (inclusive of zeromethinemerocyanine (simple merocyanine)), trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, and fused aromatic carbocyclic compounds (for example, naphthalene derivatives, anthracene derivatives, phenanthrene derivatives, tetracene derivatives, pyrene derivatives, perylene derivatives, and fluoranthene derivatives).

Next, the metal complex compound will be described. The metal complex compound is a metal complex having a ligand containing at least one of a nitrogen atom, an oxygen atom and a sulfur atom as coordinated to a metal. Though a metal ion in the metal complex is not particularly limited, it is preferably a beryllium ion, a magnesium ion, an aluminum ion, a gallium ion, a zinc ion, an indium ion, or a tin ion; more preferably a beryllium ion, an aluminum ion, a gallium ion, or a zinc ion; and further preferably an aluminum ion or a zinc ion. As the ligand which is contained in the metal complex, there are enumerated various known ligands. Examples thereof include ligands as described in H. Yersin, Photochemistry and Photophysics of Coordination Compounds, Springer-Verlag, 1987; and Akio Yamamoto, Organometallic Chemistry—Principles and Applications, Shokabo Publishing Co., Ltd., 1982.

The foregoing ligand is preferably a nitrogen-containing heterocyclic ligand (having preferably from 1 to 30 carbon atoms, more preferably from 2 to 20 carbon atoms, and especially preferably from 3 to 15 carbon atoms, which may be a monodentate ligand or a bidentate or polydentate ligand, with a bidentate ligand being preferable; and examples of which include a pyridine ligand, a bipyridyl ligand, a quinolinol ligand, and a hydroxyphenylazole ligand (for example, a hydroxyphenylbenzimidazole ligand, a hydroxyphenylbenzoxazole ligand, and a hydroxyphenylimidazole ligand), an alkoxy ligand (having preferably from 1 to 30 carbon atoms, more preferably from 1 to 20 carbon atoms, and especially preferably from 1 to 10 carbon atoms, examples of which include methoxy, ethoxy, butoxy, and 2-ethylhexyloxy), an aryloxy ligand (having preferably from 6 to 30 carbon atoms, more preferably from 6 to 20 carbon atoms, and especially preferably from 6 to 12 carbon atoms, examples of which include phenyloxy, 1-naphthyloxy, 2-naphthyloxy, 2,4,6-trimethylphenyloxy, and 4-biphenyloxy), an aromatic heterocyclic oxy ligand (having preferably from 1 to 30 carbon atoms, more preferably from 1 to 20 carbon atoms, and especially preferably from 1 to 12 carbon atoms, examples of which include pyridyloxy, pyrazyloxy, pyrimidyloxy, and quinolyloxy), an alkylthio ligand (having preferably from 1 to 30 carbon atoms, more preferably from 1 to 20 carbon atoms, and especially preferably from 1 to 12 carbon atoms, examples of which include methylthio and ethylthio), an arylthio ligand (having preferably from 6 to 30 carbon atoms, more preferably from 6 to 20 carbon atoms, and especially preferably from 6 to 12 carbon atoms, examples of which include phenylthio), a heterocyclic substituted thio ligand (having preferably from 1 to 30 carbon atoms, more preferably from 1 to 20 carbon atoms, and especially preferably from 1 to 12 carbon atoms, examples of which include pyridylthio, 2-benzimidazolylthio, 2-benzoxazolylthio, and 2-benzothiazolylthio), or a siloxy ligand (having preferably from 1 to 30 carbon atoms, more preferably from 3 to 25 carbon atoms, and especially preferably from 6 to 20 carbon atoms, examples of which include a triphenyloxy group, a triethoxysiloxy group, and a triisopropylsiloxy group); more preferably a nitrogen-containing heterocyclic ligand, an aryloxy ligand, an aromatic heterocyclic oxy ligand, or a siloxy ligand; and further preferably a nitrogen-containing heterocyclic ligand, an aryloxy ligand, or a siloxy ligand.

In the invention, the case containing a photoelectric conversion layer (photosensitive layer) having a p-type semiconductor layer and an n-type semiconductor layer between one pair of electrodes, with at least one of the p-type semiconductor layer and the n-type semiconductor layer being an organic semiconductor, and a bulk heterojunction structure layer containing the p-type semiconductor and the n-type semiconductor as an interlayer between these semiconductor layers is preferable. In such case, in the photoelectric conversion layer, by containing a bulk heterojunction structure in the organic layer, a drawback that the organic layer has a short carrier diffusion length is compensated, thereby improving the photoelectric conversion efficiency. Incidentally, the bulk heterojunction structure is described in detail in Japanese Patent Application No. 2004-080639.

In the invention, the case where a photoelectric conversion layer (photosensitive layer) having a structure having the number of a repeating structure (tandem structure) of a pn junction layer formed of the p-type semiconductor layer and the n-type semiconductor layer is contained between one pair of electrodes of 2 or more is preferable; and the case where a thin layer made of a conducting material is inserted between the foregoing repeating structures is more preferable. The number of the repeating structure (tandem structure) of a pn junction layer is not limited. For the purpose of enhancing the photoelectric conversion efficiency, the number of the repeating structure (tandem structure) of a pn junction layer is preferably from 2 to 50, more preferably from 2 to 30, and especially preferably from 2 to 10. The conducting material is preferably silver or gold, and most preferably silver. Incidentally, the tandem structure is described in detail in Japanese Patent Application No. 2004-079930.

In the photoelectric conversion layer having a layer of a p-type semiconductor and a layer of an n-type semiconductor (preferably a mixed or dispersed (bulk heterojunction structure) layer) between one pair of electrodes, the case of a photoelectric conversion layer which is characterized by containing an orientation-controlled organic compound in at least one of the p-type semiconductor and the n-type semiconductor is preferable; and the case of a photoelectric conversion layer which is characterized by containing an orientation-controlled (orientation controllable) organic compound in both the p-type semiconductor and the n-type semiconductor is more preferable. As the organic compound which is used in the organic layer of the photoelectric conversion device, an organic compound having a π-conjugated electron is preferably used. The π-electron plane is not vertical to a substrate (electrode substrate) and is oriented at an angle close to parallel to the substrate as far as possible. The angle against the substrate is preferably 0° or more and not more than 80°, more preferably 0° or more and not more than 60°, further preferably 0° or more and not more than 40°, still further preferably 0° or more and not more than 20°, especially preferably 0° or more and not more than 10°, and most preferably 0° (namely, in parallel to the substrate). As described previously, it is only required that even a part of the layer of the orientation-controlled organic compound is contained over the whole of the organic layer. A proportion of the orientation-controlled portion to the whole of the organic layer is preferably 10% or more, more preferably 30% or more, further preferably 50% or more, still further preferably 70% or more, especially preferably 90% or more, and most preferably 100%. In the photoelectric conversion layer, by controlling the orientation of the organic compound of the organic layer, the foregoing state compensates a drawback that the organic layer in the photoelectric conversion layer has a short carrier diffusion length, thereby improving the photoelectric conversion efficiency.

In the case where the orientation of an organic compound is controlled, it is more preferable that the heterojunction plane (for example, a pn junction plane) is not in parallel to a substrate. In this case, it is preferable that the heterojunction plane is not in parallel to the substrate (electrode substrate) but is oriented at an angle close to verticality to the substrate as far as position. The angle to the substrate is preferable 0° or more and not more than 90°, more preferably 30° or more and not more than 90°, further preferably 50° or more and not more than 90°, still further preferably 70° or more and not more than 90°, especially preferably 80° or more and not more than 90°, and most preferably 90° (namely, vertical to the substrate). As described previously, it is only required that even a part of the layer of the heterojunction plane-controlled organic compound is contained over the whole of the organic layer. A proportion of the orientation-controlled portion to the whole of the organic layer is preferably 10% or more, more preferably 30% or more, further preferably 50% or more, still further preferably 70% or more, especially preferably 90% or more, and most preferably 100%. In such case, the area of the heterojunction plane in the organic layer increases and the amount of a carrier such as an electron as formed on the interface, a hole, and a pair of an electron and a hole increases so that it is possible to improve the photoelectric conversion efficiency. In the light of the above, in the photoelectric conversion layer in which the orientation of the organic compound on both the heterojunction plane and the n-electron plane is controlled, it is possible to improve especially the photoelectric conversion efficiency. These states are described in detail in Japanese Patent Application No. 2004-079931.

From the standpoint of optical absorption, it is preferable that the layer thickness of the organic dye layer is as thick as possible. However, taking into consideration a proportion which does not contribute to the charge separation, the layer thickness of the organic dye layer in the invention is preferably 30 nm or more and not more than 300 nm, more preferably 50 nm or more and not more than 250 nm, and especially preferably 80 nm or more and not more than 200 nm.

(Formation Method of Organic Layer)

A layer containing such an organic compound is subjected to film formation by a dry film formation method or a wet film formation method. Specific examples of the dry film formation method include physical vapor phase epitaxy methods such as a vacuum vapor deposition method, a sputtering method, an ion plating method, and an MBE method and CVD methods such as plasma polymerization. Examples of the wet film formation method include a casting method, a spin coating method, a dipping method, and an LB method.

In the case of using a high molecular compound in at least one of the p-type semiconductor (compound) and the n-type semiconductor (compound), it is preferable that the film formation is achieved by a wet film formation method which is easy for the preparation. In the case of employing a dry film formation method such as vapor deposition, the use of a high molecular compound is difficult because of possible occurrence of decomposition. Accordingly, its oligomer can be preferably used instead of that. On the other hand, in the case of using a low molecular compound, a dry film formation method is preferably employed, and a vacuum vapor deposition method is especially preferably employed. In the vacuum vapor deposition method, a method for heating a compound such as a resistance heating vapor deposition method and an electron beam heating vapor deposition method, the shape of a vapor deposition source such as a crucible and a boat, a degree of vacuum, a vapor deposition temperature, a substrate temperature, a vapor deposition rate, and the like are a basic parameter. In order to achieve uniform vapor deposition, it is preferable that the vapor deposition is carried out while rotating the substrate. A high degree of vacuum is preferable. The vacuum vapor deposition is carried out at a degree of vacuum of not more than 10⁻⁴ Torr (1.33×10⁻² Pa), preferably not more than 10⁻⁶ Torr (1.33×10⁻⁴ Pa), and especially preferably not more than 10⁻⁸ Torr (1.33×10^{≢}Pa). It is preferable that all steps at the time of vapor deposition are carried out in vacuo. Basically, the vacuum vapor position is carried out in such a manner that the compound does not come into direct contact with the external oxygen and moisture. The foregoing conditions of the vacuum vapor deposition must be strictly controlled because they affect crystallinity, amorphous properties, density, compactness, and so no. It is preferably employed to subject the vapor deposition rate to PI or PID control using a layer thickness monitor such as a quartz oscillator and an interferometer. In the case of vapor depositing two or more kinds of compounds at the same time, a co-vapor deposition method, a flash vapor deposition method and so on can be preferably employed.

(Electrode)

The electromagnetic wave absorption/photoelectric conversion site made of an organic layer of the invention is interposed between one pair of electrodes, and a pixel electrode and a counter electrode are formed, respectively. It is preferable that the lower layer is a pixel electrode.

Examples of the counter electrode other than that of the invention include a metal, an alloy, a metal oxide, an electrically conducting compound, or a mixture thereof can be used. It is preferable that the pixel electrode extracts an electron from an electron transport photoelectric conversion layer or an electron transport layer. The pixel electrode is selected while taking into consideration adhesion to an adjacent layer such as an electron transport photoelectric conversion layer and an electron transport layer, electron affinity, ionization potential, stability, and the like. Specific examples thereof include conducting metal oxides such as tin oxide, zinc oxide, indium oxide, and indium tin oxide (ITO); metals such as gold, silver, chromium, and nickel; mixtures or stacks of such a metal and such a conducting metal oxide; inorganic conducting substances such as copper iodide and copper sulfide; organic conducting materials such as polyaniline, polythiophene, and polypyrrole; silicon compounds; and stack materials thereof with ITO. Of these, conducting metal oxides are preferable; and ITO and IZO (indium zinc oxide) are especially preferable in view of productivity, high conductivity, transparency, and so on. Though the thickness of the pixel electrode can be properly selected depending upon the material, in general, it is preferably in the range of 10 nm or more and not more than 1 μm, more preferably in the range of 30 nm or more and not more than 500 nm, and further preferably in the range of 50 nm or more and not more than 300 nm. In the preparation of the pixel electrode and the counter electrode, various methods are employable depending upon the material. For example, in the case of ITO, the layer is formed by a method such as an electron beam method, a sputtering method, a resistance heating vapor deposition method, a chemical reaction method (for example, a sol-gel method), and coating of a dispersion of indium tin oxide. In the case of ITO, a UV-ozone treatment, a plasma treatment, or the like can be applied.

It is preferable that the transparent electrode layer other than that of the invention is prepared in a plasma-free state. By preparing a transparent electrode layer in a plasma-free state, it is possible to minimize influences of the plasma against the substrate and to make photoelectric conversion characteristics satisfactory. Here, the term “plasma-free state” means a state that plasma is not generated during the film formation of a transparent electrode layer or that a distance from the plasma generation source to the substrate is 2 cm or more, preferably 10 cm or more, and more preferably 20 cm or more and that the plasma which reaches the substrate is reduced.

With respect to the device in which plasma is not generated during the film formation of a transparent electrode layer, the same device and method as described previously are applicable.

The electrode of the organic electromagnetic wave absorption/photoelectric conversion site of the invention will be hereunder described in more detail. The photoelectric conversion layer as an organic layer is interposed between a pixel electrode layer and a counter electrode layer and can contain an interelectrode material or the like. The “pixel electrode layer” as referred to herein refers to an electrode layer as prepared above a substrate in which a charge storage/transfer/read-out site is formed and is usually divided for every one pixel. This is made for the purpose of obtaining an image by reading out a signal charge which has been converted by the photoelectric conversion layer on a charge storage/transfer/signal read-out circuit substrate for every one pixel.

The “counter electrode layer” as referred to herein has a function to discharge a signal charge having a reversed polarity to a signal charge by interposing the photoelectric conversion layer together with the pixel electrode layer. Since this discharge of a signal charge is not required to be divided among the respective pixels, the counter electrode layer can be usually made common among the respective pixels. For that reason, the counter electrode layer is sometimes called a common electrode layer.

The photoelectric conversion layer is positioned between the pixel electrode layer and the counter electrode layer. The photoelectric conversion function functions by this photoelectric convention layer and the pixel electrode layer and the counter electrode layer.

As examples of the configuration of the photoelectric conversion layer stack, first of all, in the case where one organic layer is stacked on a substrate, there is enumerated a construction in which a pixel electrode layer (basically a transparent electrode layer, which is corresponding to the conducting thin layer of the invention), a photoelectric conversion layer (corresponding to the photoelectric conversion layer of the invention) and a counter electrode layer (transparent electrode layer, which is corresponding to the transparent conducting thin layer) are stacked in this order from the substrate. However, it should not be construed that the invention is limited thereto.

In addition, in the case where two organic layers are stacked on a substrate, there is enumerated a construction in which a pixel electrode layer (basically a transparent electrode layer), a photoelectric conversion layer, a counter electrode layer (transparent electrode layer), an interlaminar insulating layer, a pixel electrode layer (basically a transparent electrode layer), a photoelectric conversion layer, and a counter electrode layer (transparent electrode layer) are stacked in this order from the substrate.

With respect to the material of the transparent electrode layer other than that of the invention, which configures the photoelectric conversion site, a material the same as the material of the transparent conducting thin layer of the invention is useful.

As the material of the transparent electrode layer, any one material of ITO, IZO, SnO₂, ATO (antimony-doped tin oxide), ZnO, AZO (Al-doped zinc oxide), GZO (gallium-doped zinc oxide), TiO₂, or FTO (fluorine-doped tin oxide) is especially preferable. A light transmittance of the transparent electrode layer is preferably 60% or more, more preferably 80% or more, further preferably 90% or more, and still further preferably 95% or more at a photoelectric conversion optical absorption peak wavelength of the photoelectric conversion layer to be contained in a photoelectric conversion device containing that transparent electrode layer. Furthermore, with respect to a surface resistance of the transparent electrode layer, its preferred range varies depending upon whether the transparent electrode layer is a pixel electrode or a counter electrode, whether the charge storage/transfer/read-out site is of a CCD structure or a CMOS structure, and the like. In the case where the transparent electrode layer is used for a counter electrode and the charge storage/transfer/read-out site is of a CMOS structure, the surface resistance is preferably not more than 10,000 Ω/□, and more preferably not more than 1,000 Ω/□. In the case where the transparent electrode layer is used for a counter electrode and the charge storage/transfer/read-out site is of a CCD structure, the surface resistance is preferably not more than 1,000 Ω/□, and more preferably not more than 100 Ω/□. In the case where the transparent electrode layer is used for a pixel electrode, the surface resistance is preferably not more than 1,000,000 Ω/□, and more preferably not more than 100,000 Ω/□.

Conditions at the time of film formation of a transparent electrode layer other than that of the invention will be hereunder mentioned. A substrate temperature at the time of film formation of a transparent electrode layer is preferably not higher than 500° C., more preferably not higher than 300° C., further preferably not higher than 200° C., and still further preferably not higher than 150° C. Furthermore, a gas may be introduced during the film formation of a transparent electrode. Basically, though the gas species is not limited, Ar, He, oxygen, nitrogen, and so on can be used. Furthermore, a mixed gas of such gases may be used. In particular, in the case of an oxide material, since oxygen deficiency often occurs, it is preferred to use oxygen.

The case of applying voltage to the photoelectric conversion layer of the invention is preferable in view of improving the photoelectric conversion efficiency. Though any voltage is employable as the voltage to be applied, necessary voltage varies with the layer thickness of the photoelectric conversion layer. That is, the larger an electric field to be added in the photoelectric conversion layer, the more improved the photoelectric conversion efficiency is. However, even when the same voltage is applied, the thinner the layer thickness of the photoelectric conversion layer, the larger an electric field to be applied is. Accordingly, in the case where the layer thickness of the photoelectric conversion film is thin, the voltage to be applied may be relatively small. The electric field to be applied to the photoelectric conversion layer is preferably 10 V/cm or more, more preferably 1×10³ V/cm or more, further preferably 1×10⁵ V/cm or more, especially preferably 1×10⁶ V/cm or more, and most preferably 1×10⁷ V/cm or more. Though there is no particular upper limit, when the electric field is excessively applied, an electric current flows even in a dark place and therefore, such is not preferable. The electric field is preferably not more than 1×10¹² V/cm, and more preferably not more than 1×10⁹ V/cm.

(Inorganic Layer)

An inorganic layer as the electromagnetic wave absorption/photoelectric conversion site will be hereunder described. In this case, light which has passed through the organic layer as the upper layer is subjected to photoelectric conversion in the inorganic layer. With respect to the inorganic layer, pn junction or pin junction of crystalline silicon, amorphous silicon, or a chemical semiconductor such as GaAs is generally employed. With respect to the stack type structure, a method as disclosed in U.S. Pat. No. 5,965,875 can be employed. That is, a construction in which a light receiving part as stacked by utilizing wavelength dependency of a coefficient of absorption of silicon is formed and color separation is carried out in a depth direction thereof. In this case, since the color separation is carried out with a light penetration depth of silicon, a spectrum range as detected in each of the stacked light receiving parts becomes broad. However, by using the foregoing organic layer as the upper layer, namely by detecting the light which has transmitted through the organic layer in the depth direction of silicon, the color separation is remarkably improved. In particular, when a G layer is disposed in the organic layer, since light which has transmitted through the organic layer is B light and R light, only BR light is subjective to separation of light in the depth direction in silicon so that the color separation is improved. Even in the case where the organic layer is a B layer or an R layer, by properly selecting the electromagnetic wave absorption/photoelectric conversion site of silicon in the depth direction, the color separation is remarkably improved. In the case where the organic layer is made of two layers, the function as the electromagnetic wave absorption/photoelectric conversion site of silicon may be brought for only one color, and preferred color separation can be achieved.

The inorganic layer preferably has a structure in which plural photodiodes are superposed for every pixel in a depth direction within the semiconductor substrate and a color signal corresponding to a signal charge as generated in each of the photodiodes by light as absorbed in the plural photodiodes is read out into the external. It is preferable that the plural photodiodes contain a first photodiode as provided in the depth for absorbing B light and at least one second photodiode as provided in the depth for absorbing R light and are provided with a color signal read-out circuit for reading out a color signal corresponding to the foregoing signal charge as generated in each of the foregoing plural photodiodes. According to this construction, it is possible to carry out color separation without using a color filter. Furthermore, according to circumstances, since light of a negative sensitive component can also be detected, it becomes possible to realize color imaging with good color reproducibility. Moreover, in the invention, it is preferable that a junction part of the foregoing first photodiode is formed in a depth of up to about 0.2 μm from the semiconductor substrate surface and that a junction part of the foregoing second photodiode is formed in a depth of up to about 2 μm from the semiconductor substrate surface.

The inorganic layer will be hereunder described in more detail. Preferred examples of the construction of the inorganic layer include a photoconductive type, a p-n junction type, a shotkey junction type, a PIN junction type, a light receiving device of MSM (metal-semiconductor-metal) type, and a light receiving device of phototransistor type. In the invention, it is preferred to use a light receiving device in which a plural number of a first conducting type region and a second conducting type region which is a reversed conducting type to the first conducting type are alternately stacked within a single semiconductor substrate and each of the junction planes of the first conducting type and second conducting type regions is formed in a depth suitable for subjecting mainly plural lights of a different wavelength region to photoelectric conversion. The single semiconductor substrate is preferably mono-crystalline silicon, and the color separation can be carried out by utilizing absorption wavelength characteristics relying upon the depth direction of the silicon substrate.

As the inorganic semiconductor, InGaN based, InAlN based, InAlP based, or InGaAlP based inorganic semiconductors can also be used. The InGaN based inorganic semiconductor is an inorganic semiconductor as adjusted so as to have a maximum absorption value within a blue wavelength range by properly changing the In-containing composition. That is, the composition becomes InₓGa₁₋ₓN (0<x<1). Such a compound semiconductor is produced by employing a metal organic chemical vapor deposition method (MOCVD method). With respect to the InAlN based nitride semiconductor using, as a raw material, Al of the Group 13 similar to Ga, it can be used as a short wavelength light receiving part similar to the InGaN based semiconductor. Furthermore, InAlP or InGaAlP lattice-matching with a GaAs substrate can also be used.

The inorganic semiconductor may be of a buried structure. The “buried structure” as referred to herein refers to a construction in which the both ends of a short wavelength light receiving part are covered by a semiconductor different from the short wavelength light receiving part. The semiconductor for covering the both ends is preferably a semiconductor having a band gap wavelength shorter than or equal to a hand gap wavelength of the short wavelength light receiving part.

The organic layer and the inorganic layer may be bound to each other in any form. Furthermore, for the purpose of electrically insulating the organic layer and the inorganic layer from each other, it is preferred to provide an insulating layer therebetween.

With respect to the junction, npn junction or pnpn junction from the light incident side is preferable. In particular, the pnpn junction is more preferable because by providing a p layer on the surface and increasing a potential of the surface, it is possible to trap a hole as generated in the vicinity of the surface and a dark current and reduce the dark current.

In such a photodiode, when an n-type layer, a p-type layer, an n-type layer and a p-type layer which are successively diffused from the p-type silicon substrate surface are deeply formed in this order, the pn-junction diode is formed of four layers of pnpn in a depth direction of silicon. With respect to the light which has come into the diode from the surface side, the longer the wavelength, the deeper the light penetration is. Also, the incident wavelength and the attenuation coefficient are inherent to silicon. Accordingly, the photodiode is designed such that the depth of the pn junction plane covers respective wavelength bands of visible light. Similarly, a junction diode of three layers of npn is obtained by forming an n-type layer, a p-type layer and n-type layer in this order. Here, a light signal is extracted from the n-type layer, and the p-type layer is connected to a ground wire.

Furthermore, when an extraction electrode is provided in each region and a prescribed reset potential is applied, each region is depleted, and the capacity of each junction part becomes small unlimitedly. In this way, it is possible to make the capacity as generated on the junction plane extremely small.

(Auxiliary Layer)

In the invention, it is preferred to provide an ultraviolet light absorption layer and/or an infrared light absorption layer as an uppermost layer of the electromagnetic wave absorption/photoelectric conversion site. The ultraviolet light absorption layer is able to at least absorb or reflect light of not more than 400 nm and preferably has an absorptance of 50% or more in a wavelength region of not more than 400 nm. The infrared light absorption layer is able to at least absorb or reflect light of 700 nm or more and preferably has an absorptance of 50% or more in a wavelength region of 700 nm or more.

Such an ultraviolet light absorption layer or infrared light absorption layer can be formed by a conventionally known method. For example, there is known a method in which a mordant layer made of a hydrophilic high molecular substance such as gelatin, casein, glue, and polyvinyl alcohol is provided on a substrate and a dye having a desired absorption wavelength is added to or dyes the mordant layer to form a colored layer. In addition, there is known a method of using a colored resin resulting from dispersing a certain kind of coloring material in a transparent resin. For example, it is possible to use a colored resin layer resulting from mixing a coloring material in a polyamino based resin as described in JP-A-58-46325, JP-A-60-78401, JP-A-60-184202, JP-A-60-184203, JP-A-60-184204, and JP-A-60-184205. A coloring agent using a polyamide resin having photosensitivity can also be used.

It is also possible to disperse a coloring material in an aromatic polyamide resin containing a photosensitive group in the molecule thereof and capable of obtaining a cured layer at not higher than 200° C. as described in JP-B-7-113685 and to use a colored resin having a pigment dispersed therein as described in JP-B-7-69486.

In the invention, a dielectric multiple layer is preferably used. The dielectric multiple layer has sharp wavelength dependency of light transmission and is preferably used.

It is preferable that the respective electromagnetic wave absorption/photoelectric conversion sites are separated by an insulating layer. The insulating layer can be formed by using a transparent insulating material such as glass, polyethylene, polyethylene terephthalate, polyethersulfone, and polypropylene. Silicon nitride, silicon oxide, and the like are also preferably used. Silicon nitride prepared by film formation by plasma CVD is preferably used in the invention because it is high in compactness and good in transparency.

For the purpose of preventing contact with oxygen, moisture, etc., a protective layer or a sealing layer can be provided, too.

Examples of the protective layer include a diamond thin layer, an inorganic material layer made of a metal oxide, a metal nitride, etc., a high molecular layer made of a fluorine resin, poly-p-xylene, polyethylene, a silicone resin, a polystyrene resin, etc., and a layer made of a photocurable resin. Furthermore, it is also possible to cover a device portion by glass, a gas-impermeable plastic, a metal, etc. and package the device itself by a suitable sealing resin. In this case, it is also possible to make a substance having high water absorption properties present in a packaging.

In addition, light collecting efficiency can be improved by forming a microlens array in the upper part of a light receiving device, and therefore, such an embodiment is preferable, too.

(Charge Storage/Transfer/Read-Out Site)

As to the charge storage/transfer/read-out site, JP-A-58-103166, JP-A-58-103165, JP-A-2003-332551, and so on can be made hereof by reference. A construction in which an MOS transistor is formed on a semiconductor substrate for every pixel unit or a construction having CCD as a device can be properly employed. For example, in the case of a photoelectric conversion device using an MOS transistor, a charge is generated in a photoelectric conversion layer by incident light which has transmitted through electrodes; the charge runs to the electrodes within the photoelectric conversion layer by an electric field as generated between the electrodes by applying voltage to the electrodes; and the charge is further transferred to a charge storage part of the MOS transistor and stored in the charge storage part. The charge as stored in the charge storage part is transferred to a charge read-out part by switching of the MOS transistor and further outputted as an electric signal. In this way, full-color image signals are inputted in a solid imaging device including a signal processing part.

The signal charge can be read out by injecting a fixed amount of bias charge into the storage diode (refresh mode) and then storing a fixed amount of the charge (photoelectric conversion mode). The light receiving device itself can be used as the storage diode, or an storage diode can be separately provided.

The read-out of the signal will be hereunder described in more detail. The read-out of the signal can be carried out by using a usual color read-out circuit. A signal charge or a signal current which is subjected to light/electric conversion in the light receiving part is stored in the light receiving part itself or a capacitor as provided. The stored charge is subjected to selection of a pixel position and read-out by a measure of an MOS type imaging device (so-called CMOS sensor) using an X-Y address system. Besides, as an address selection system, there is enumerated a system in which every pixel is successively selected by a multiplexer switch and a digital shift register and read out as a signal voltage (or charge) on a common output line. An imaging device of a two-dimensionally arrayed X-Y address operation is known as a CMOS sensor. In this imaging device, a switch as provided in a pixel connected to an X-Y intersection point is connected to a vertical shift register, and when the switch is turned on by a voltage from the vertical scanning shift register, signals as read out from pixels as provided in the same line is read out on the output line in a column direction. The signals are successively read out from an output end through the switch to be driven by a horizontal scanning shift register.

For reading out the output signals, a floating diffusion detector or a floating gate detector can be used. Furthermore, it is possible to seek improvements of S/N by a measure such as provision of a signal amplification circuit in the pixel portion and correlated double sampling.

For the signal processing, gamma correction by an ADC circuit, digitalization by an AD transducer, luminance signal processing, and color signal processing can be applied. Examples of the color signal processing include white balance processing, color separation processing, and color matrix processing. In using for an NTSC signal, an RGB signal can be subjected to conversion processing of a YIQ signal.

The charge transfer/read-out site must have a mobility of charge of 100 cm²/vol·sec or more. This mobility can be obtained by selecting the material among semiconductors of the IV group, the III-V group or the II-VI group. Above all, silicon semiconductors (also referred to as “Si semiconductor”) are preferable because of advancement of microstructure refinement technology and low costs. As to the charge transfer/charge read-out system, there are made a number of proposals, and all of them are employable. Above all, a COMS type device or a CCD type device is an especially preferred system. In addition, in the case of the invention, in many occasions, the CMOS type device is preferable in view of high-speed read-out, pixel addition, partial read-out and consumed electricity.

(Connection)

Though plural contact sites for connecting the electromagnetic wave absorption/photoelectric conversion side to the charge transfer/read-out site may be connected by any metal, a metal selected among copper, aluminum, silver, gold, chromium and tungsten is preferable, and copper is especially preferable. In response to the plural electromagnetic wave absorption/photoelectric conversion sites, each of the contact sites must be placed between the electromagnetic wave absorption/photoelectric conversion site and the charge transfer/read-out site. In the case of employing a stacked structure of plural photosensitive units of blue, green and red lights, a blue light extraction electrode and the charge transfer/read-out site, a green light extraction electrode and the charge transfer/read-out site, and a red light extraction electrode and the charge transfer/read-out site must be connected, respectively.

(Process)

The stacked photoelectric conversion device of the invention can be produced according to a so-called known microfabrication process which is employed in manufacturing integrated circuits and the like. Basically, this process is concerned with a repeated operation of pattern exposure with active light, electron beams, etc. (for example, i- or g-bright line of mercury, excimer laser, X-rays, and electron beams), pattern formation by development and/or burning, alignment of device forming materials (for example, coating, vapor deposition, sputtering, and CV), and removal of the materials in a non-pattern area (for example, heat treatment and dissolution treatment).

(Utility)

A chip size of the device can be selected among a brownie size, a 135 size, an APS size, a 1/1.8-inch size, and a smaller size. A pixel size of the stacked photoelectric conversion device of the invention is expressed by a circle-corresponding diameter which is corresponding to a maximum area in the plural electromagnetic absorption/photoelectric conversion sites. Though the pixel size is not limited, it is preferably from 2 to 20 microns, more preferably from 2 to 10 microns, and especially preferably from 3 to 8 microns.

When the pixel size exceeds 20 microns, a resolving power is lowered, whereas when the pixel size is smaller than 2 microns, the resolving power is also lowered due to radio interference between the sizes.

The stacked photoelectric conversion device of the invention can be utilized for a digital still camera. Also, it is preferable that the photoelectric conversion device of the invention is used for a TV camera. Besides, the photoelectric conversion device of the invention can be utilized for a digital video camera, a monitor camera (in, for example, office buildings, parking lots, unmanned loan-application systems in financial institution, shopping centers, convenience stores, outlet malls, department stores, pachinko parlors, karaoke boxes, game centers, and hospitals), other various sensors (for example, TV door intercoms, individual authentication sensors, sensors for factory automation, robots for household use, industrial robots, and piping examination systems), medical sensors (for example, endoscopes and fundus cameras), videoconference systems, television telephones, camera-equipped mobile phones, automobile safety running systems (for example, back guide monitors, collision prediction systems, and lane-keeping systems), and sensors for video game.

Above all, the photoelectric conversion device of the invention is suitable for use of a television camera. The reason for this resides in the matter that since it does not require a color decomposition optical system, it is able to achieve miniaturization and weight reduction of the television camera. Furthermore, since the photoelectric conversion device of the invention has high sensitivity and high resolving power, it is especially preferable for a television camera for high-definition broadcast. In this case, the term “television camera for high-definition broadcast” as referred to herein includes a camera for digital high-definition broadcast.

In addition, the photoelectric conversion device of the invention is preferable because an optical low pass filter can be omitted and higher sensitivity and higher resolving power can be expected.

In addition, in the photoelectric conversion device of the invention, not only the thickness can be made thin, but also a color decomposition optical system is not required. Therefore, with respect to shooting scenes in which a different sensitivity is required, such as “circumstances with a different brightness such as daytime and nighttime” and “immobile subject and mobile subject” and other shooting scenes in which requirements for spectral sensitivity or color reproducibility differ, various needs for shooting can be satisfied by a single camera by exchanging the photoelectric conversion device of the invention and performing shooting. At the same time, it is not required to carry plural cameras. Thus, a load of a person who wishes to take a shot is reduced. As a photoelectric conversion device which is subjective to the exchange, in addition to the foregoing, exchangeable photoelectric conversion devices for purposes of infrared light shooting, black-and-white shooting, and change of a dynamic range can be prepared.

The TV camera of the invention can be prepared by referring to a description in Chapter 2 of Design Technologies of Television Camera, edited by the Institute of Image Information and Television Engineers (Aug. 20, 1999, published by Corona Publishing Co., Ltd., ISBN 4-339-00714-5) and, for example, replacing a color decomposition optical system and an imaging device as a basic construction of a television camera as shown in FIG. 2.1 thereof by the photoelectric conversion device of the invention.

By aligning the foregoing stacked light receiving device, it can be utilized not only as an imaging device but also as an optical sensor such as biosensors and chemical sensors or a color light receiving device in a single body.

(Preferred Photoelectric Conversion Device of the Invention)

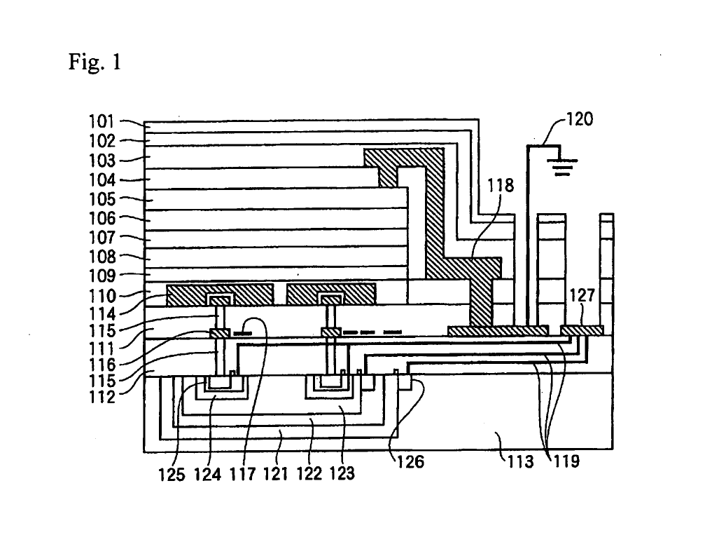

A preferred photoelectric conversion device of the invention will be hereunder described with reference to FIG. 1. A numeral 113 is a silicon mono-crystal substrate and serves as both an electromagnetic wave absorption/photoelectric conversion site of B light and R light and a charge storage of charge as generated by photoelectric conversion/transfer/and read-out site. Usually, a p-type silicon substrate is used. Numerals 121, 122 and 123 represent an n layer, a p layer and an n layer, respectively as provided in the silicon substrate. The n layer 121 is an storage part of a signal charge of R light and stores a signal charge of R light which has been subjected to photoelectric conversion by pn junction. The stored charge is connected to a signal read-out pad 127 by a metal wiring 119 via a transistor 126. The n layer 123 is an storage part of a signal charge of B light and stores a signal charge of B light which has been subjected to photoelectric conversion by pn junction. The stored charge is connected to the signal read-out pad 127 by the metal wiring 119 via a transistor similar to the transistor 126. Here, though the p layer, the n layer, the transistor, the metal wiring, and the like are schematically shown, each of them is properly selected among optimum structures and so on as described previously in detail. Since the B light and the R light are divided depending upon the depth of the silicon substrate, it is important to select the depth of the pn junction, etc. from the silicon substrate, the dope concentration and so on. A numeral 112 is a layer containing a metal wiring and is a layer containing, as a major component, silicon oxide, silicon nitride, etc. It is preferable that the thickness of the layer 112 is thin as far as possible. The thickness of the layer 112 is not more than 5 μm, preferably not more than 3 μm, and further preferably not more than 2 μm. A numeral 111 is also a layer containing, as a major component, silicon oxide, silicon nitride, etc. The layers 111 and 112 are each provided with a plug for sending a signal charge of G light to the silicon substrate. The plugs are connected to each other between the layers 111 and 112 by a pad 116. As the plug, one containing, as a major component, tungsten is preferably used. As the pad, one containing, as a major component, aluminum is preferably used. It is preferable that a barrier layer including the foregoing metal wiring is provided. The signal charge of G light which is sent via plugs 115 is stored in a layer 125 in the silicon substrate. The n layer 125 is separated by a p layer 124. The stored charge is connected to the signal read-out pad 127 by the metal wiring 119 via the transistor similar to the transistor 126. Since the photoelectric conversion by the pn junction by the layers 124 and 125 becomes a noise, a light shielding layer 117 is provided in the layer 111. As the light shielding layer, one containing, as a major component, tungsten, aluminum, etc. is usually used. It is preferable that the thickness of the layer 112 is thin as far as possible. The thickness of the layer 112 is not more than 3 μm, preferably not more than 2 μm, and further preferably not more than 1 μm. It is preferable that the signal read-out pad 127 is provided for every signal of the B, G and R signals. The foregoing process can be achieved by a conventionally known process, a so-called CMOS process.

The electromagnetic wave absorption/photoelectric conversion site of G light is shown by numerals 105, 106, 107, 108, 109, 110 and 114. The numerals 105 and 114 are each a transparent electrode and are corresponding to a counter electrode and a pixel electrode, respectively. Though the pixel electrode 114 is a transparent electrode, for the purpose of enhancing the electric connection with the plug 115, in many cases, a site made of aluminum, molybdenum, etc. is required in the connecting part. These transparent electrodes are biased through a wiring from a connection electrode 118 and a counter electrode pad 120. A structure in which an electron can be stored in the layer 125 by positively biasing the pixel electrode 114 against the transparent counter electrode 105 is preferable. In this case, the numeral 107 is an electron blocking layer; the numeral 108 is a p layer; the numeral 109 is an n layer; and the numeral 110 is a hole blocking layer. Here, a representative layer construction of the organic layer was shown. The numeral 106 is a buffer layer, and the thickness of the organic layer made of the layers 107, 108, 109 and 110 is preferably not more than 0.5 μm, more preferably not more than 0.35 μm, further preferably not more than 0.3 μm, and especially preferably not more than 0.2 μm in total. The numeral 105 is a transparent counter electrode, and the thickness of the transparent pixel electrode 114 is especially preferably not more than 0.2 μm. Numerals 103 and 104 are each a protective layer containing, as a major component, silicon nitride, etc. By these protective layers, it becomes easy to achieve a manufacturing process of layers containing the organic layer. In particular, these layers are able to reduce damages against the organic layer at the time of resist pattern preparation and etching during the preparation of the connection electrode 118 and the like. Furthermore, in order to avoid the resist pattern preparation, the etching and the like, it is also possible to achieve the production using a mask. So far as the foregoing conditions are met, the thickness of each of the protective layers 103 and 104 is preferably not more than 0.5 μm.

The numeral 103 is a protective layer of the connection electrode 118. A numeral 102 is an infrared light-cut dielectric multiple layer. A numeral 101 is an antireflection layer. A total thickness of the layers 101, 102 and 103 is preferably not more than 1 μm.

The photoelectric conversion device as described previously by FIG. 1 is constructed of one pixel for each of the B pixel and the R pixel vs. four pixels for the G pixel. The photoelectric conversion device may be constructed of one pixel for each of the B pixel and the R pixel vs. one pixel for the G pixel; may be constructed of one pixel for each of the B pixel and the R pixel vs. three pixel for the G pixel; and may be constructed of one pixel for each of the B pixel and the R pixel vs. two pixels for the G pixel. In addition, the photoelectric conversion device may be constructed of an arbitrary combination. While preferred embodiments of the invention have been described, it should not be construed that the invention is limited thereto.

### EXAMPLES

The invention will be hereunder described with reference to the following Example, but it should not be construed that the invention is limited thereto.

### Example 1

In the foregoing preferred photoelectric conversion device structure, ITO was used as the transparent pixel electrode 114 of each of the invention and the comparison, and its thickness was 100 nm. ITO was used as the transparent electrode 105 of each of the invention and the comparison, and its thickness was 10 nm for the invention and 50 nm for the comparison, respectively. With respect to the film formation method the transparent pixel electrode, an RF magnetron sputtering method (TS distance: 10 cm) was employed, the amount of introduction of O₂ was 0%, and the temperature at the time of film formation was 25° C. On the other hand, with respect to the transparent electrode of the invention, an RF magnetron sputtering method (TS distance: 10 cm) was employed, the amount of introduction of O₂ was 0%, the temperature at the time of film formation was 25° C., and the time for the film formation was 4 minutes and 50 seconds (290 seconds). With respect to the transparent electrode of the comparison, a RF magnetron sputtering method (TS distance: 10 cm) was employed, the amount of introduction of O₂ was 0%, the temperature at the time of film formation was 25° C., and the time for the film formation was 23 minutes and 30 seconds (1410 seconds). In place of the organic layers 107 to 110 of the preferred photoelectric conversion device, tris-8-hydroxyquionoline aluminum (Alq) and 2,9-dimethylquinacridone were subjected to film formation from the substrate side by heat vapor deposition in a thickness of 50 μm and 100 nm, respectively. At the time of applying a voltage of 1 V to the side of the transparent electrode 105, when a dark current value of the comparison was defined as 1, it was reduced to 0.001 in the invention.

According to the invention, a device with satisfactory S/N ratio could be prepared.

The photoelectric conversion device of the invention can be applied to imaging devices including digital cameras, video cameras, facsimiles, scanners, and copiers. The photoelectric conversion device of the invention is also applicable to optical sensors such as biosensors and chemical sensors.

This application is based on Japanese Patent application JP 2005-240963, filed Aug. 23, 2005, the entire content of which is hereby incorporated by reference, the same as if set forth at length.

What is claimed is:

1. A photoelectric conversion device comprising: a substrate; a conducting layer; a photoelectric conversion layer; and a transparent conducting layer provided in this order, wherein the transparent conducting layer has a thickness of not more than ⅕ of that of the photoelectric conversion layer.

2. The photoelectric conversion device according to claim 1, wherein the transparent conducting layer has a thickness of not more than 1/10 of that of the photoelectric conversion layer.

3. A photoelectric conversion device comprising: a substrate; a conducting layer; a photoelectric conversion layer; and a transparent conducting layer provided in this order, wherein the transparent conducting layer has a thickness of from 5 nm to 30 nm.

4. The photoelectric conversion device according to claim 1, wherein the photoelectric conversion layer has a thickness of not more than 350 nm.

5. The photoelectric conversion device according to claim 1, wherein the transparent conducting layer contains a transparent conducting oxide.

6. The photoelectric conversion device according to claim 3, wherein the transparent conducting layer contains a transparent conducting oxide.

7. The photoelectric conversion device according to claim 1, wherein the transparent conducting layer has a light transmittance of 75% or more at a light wavelength in a range of from 400 to 700 nm.

8. The photoelectric conversion device according to claim 3, wherein the transparent conducting layer has a light transmittance of 75% or more at a light wavelength in a range of from 400 to 700 nm.

9. The photoelectric conversion device according to claim 1, wherein the transparent conducting layer has a sheet resistance of from 100 Ω/□ to 10,000 Ω/□.

10. The photoelectric conversion device according to claim 3, wherein the transparent conducting layer has a sheet resistance of from 100 Ω/□ to 10,000 Ω/□.

11. The photoelectric conversion device according to claim 1, wherein the transparent conducting layer is subjected to film formation by a plasma-free method.

12. The photoelectric conversion device according to claim 3, wherein the transparent conducting layer is subjected to film formation by a plasma-free method.

13. The photoelectric conversion device according to claim 1, wherein the photoelectric conversion layer includes a pigment based material layer.

14. The photoelectric conversion device according to claim 3, wherein the photoelectric conversion layer includes a pigment based material layer.

15. The photoelectric conversion device according to claim 13, wherein the pigment based material layer has a thickness of 75 nm or more.

16. The photoelectric conversion device according to claim 14, wherein the pigment based material layer has a thickness of 75 nm or more.

17. The photoelectric conversion device according to claim 13, wherein the pigment based material layer has a thickness of 100 m or more.

18. The photoelectric conversion device according to claim 14, wherein the pigment based material layer has a thickness of 100 m or more.

19. A photoelectric conversion device comprising: a semiconductor substrate; an inorganic photoelectric conversion layer provided in the semiconductor substrate; and the photoelectric conversion layer according to claim 1 stacked above the inorganic photoelectric conversion layer.

20. An imaging device comprising the photoelectric conversion device according to claim 1.

21. A photoelectric conversion device comprising: a semiconductor substrate; an inorganic photoelectric conversion layer provided in the semiconductor substrate; and the photoelectric conversion layer according to claim 3 stacked above the inorganic photoelectric conversion layer.

22. An imaging device comprising the photoelectric conversion device according to claim 3.
